(19) United States
(12) Patent Application Publication
(10) Pub. No.: US 2025/0278819 A1
(43) Pub. Date: Sep. 4, 2025

(54) SYSTEM AND METHOD FOR ENHANCING PROPELLER IMAGE QUALITY BY UTILIZING MULTI-LEVEL DENOISING

(71) Applicant: GE Precision Healthcare LLC, Waukesha, WI (US)

(72) Inventors: Florintina Chaarlas, Bangalore (IN); Suresh Emmanuel Devadoss Joel, Bangalore (IN)

(21) Appl. No.: 18/592,975

(22) Filed: Mar. 1, 2024

(51) Int. Cl. G06T 5/60; G01R 33/565; G06T 3/4053; G06T 5/70; G06T 11/00

(52) U.S. Cl. CPC G06T 5/60; G01R 33/565; G06T 3/4053; G06T 5/70; G06T 11/006; G06T 2207/10088; G06T 2207/20056; G06T 2207/20081; G06T 2207/20084; G06T 2207/30004; G06T 2210/41; G06T 2211/441; G06T 2211/448

(57) ABSTRACT

A system and method for improving image quality of periodically rotated overlapping parallel lines with enhanced reconstruction (PROPELLER) imaging include acquiring a plurality of blades of k-space data of a region of interest in a rotational manner around a center of k-space via a magnetic resonance imaging (MRI) scanner from a coil during a PROPELLER sequence, wherein each blade of the plurality of blades of k-space data includes a plurality of parallel phase encoding lines sampled in a phase encoding order. The system and method also include utilizing a deep learning-based multi-level denoising network to denoise each blade of the plurality of blades in an image domain to generate a plurality of denoised blades, to utilize a PROPELLER reconstruction algorithm to generate a denoised-gridded image from the plurality of denoised blades, and to remove individual-based denoising-induced artifacts from the denoised-gridded image to generate a denoised, artifact-free gridded image.

### BACKGROUND

The subject matter disclosed herein relates to medical imaging and, more particularly, to a system and a method for enhancing propeller image quality by utilizing multi-level denoising.

Non-invasive imaging technologies allow images of the internal structures or features of a patient/object to be obtained without performing an invasive procedure on the patient/object. In particular, such non-invasive imaging technologies rely on various physical principles (such as the differential transmission of X-rays through a target volume, the reflection of acoustic waves within the volume, the paramagnetic properties of different tissues and materials within the volume, the breakdown of targeted radionuclides within the body, and so forth) to acquire data and to construct images or otherwise represent the observed internal features of the patient/object.

During magnetic resonance imaging (MRI), when a substance such as human tissue is subjected to a uniform magnetic field (polarizing field B₀), the individual magnetic moments of the spins in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, or “longitudinal magnetization”, M_{z}, may be rotated, or “tipped”, into the x-y plane to produce a net transverse magnetic moment, Mₜ. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradient fields vary according to the particular localization method being used. The resulting set of received nuclear magnetic resonance (NMR) signals are digitized and processed to reconstruct the image using one of many well-known reconstruction techniques.

Periodically rotated overlapping parallel lines with enhanced reconstruction (PROPELLER) is an MR technique which provides high resolution magnetic resonance imaging with reduced motion artifacts by providing the capability to remove motion affected blades and by oversampling the low spatial frequencies. While the noise is Gaussian in each blade, after gridding the blades into a Cartesian matrix, the noise becomes colored. Attempts at denoising colored noise are reported to produce blurriness and degraded image quality. The denoising performance becomes drastically worse in the case of low signal-to-noise ratio data.

### BRIEF DESCRIPTION

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, computer-implemented method for improving image quality of periodically rotated overlapping parallel lines with enhanced reconstruction (PROPELLER) imaging is provided. The computer-implemented method includes acquiring, via a processor, a plurality of blades of k-space data of a region of interest in a rotational manner around a center of k-space via a magnetic resonance imaging (MRI) scanner from a coil during a PROPELLER sequence, wherein each blade of the plurality of blades of k-space data includes a plurality of parallel phase encoding lines sampled in a phase encoding order. The computer-implemented method also includes utilizing, via the processor, a deep learning-based multi-level denoising network to denoise each blade of the plurality of blades in an image domain to generate a plurality of denoised blades, to utilize a PROPELLER reconstruction algorithm to generate a denoised-gridded image from the plurality of denoised blades, and to remove individual-based denoising-induced artifacts from the denoised-gridded image to generate a denoised, artifact-free gridded image.

In another embodiment, a system for improving image quality of periodically rotated overlapping parallel lines with enhanced reconstruction (PROPELLER) imaging is provided. The system includes a memory encoding processor-executable routines. The system also includes a processor configured to access the memory and to execute the processor-executable routines, wherein the processor-executable routines, when executed by the processor, cause the processor to perform actions. The actions include acquiring a plurality of blades of k-space data of a region of interest in a rotational manner around a center of k-space via a magnetic resonance imaging (MRI) scanner from a coil during a PROPELLER sequence, wherein each blade of the plurality of blades of k-space data includes a plurality of parallel phase encoding lines sampled in a phase encoding order. The actions also include utilizing a deep learning-based multi-level denoising network to denoise each blade of the plurality of blades in an image domain to generate a plurality of denoised blades, to utilize a PROPELLER reconstruction algorithm to generate a denoised-gridded image from the plurality of denoised blades, and to remove individual-based denoising-induced artifacts from the denoised-gridded image to generate a denoised, artifact-free gridded image.

In a further embodiment, a non-transitory computer-readable medium, the computer-readable medium including processor-executable code that when executed by a processor, causes the processor to perform actions. The actions include acquiring a plurality of blades of k-space data of a region of interest in a rotational manner around a center of k-space via a magnetic resonance imaging (MRI) scanner from a coil during a PROPELLER sequence, wherein each blade of the plurality of blades of k-space data includes a plurality of parallel phase encoding lines sampled in a phase encoding order. The actions also include utilizing a deep learning-based multi-level denoising network to denoise each blade of the plurality of blades in an image domain to generate a plurality of denoised blades, to utilize a PROPELLER reconstruction algorithm to generate a denoised-gridded image from the plurality of denoised blades, and to remove individual-based denoising-induced artifacts from the denoised-gridded image to generate a denoised, artifact-free gridded image.

### BRIEF DESCRIPTION OF THE DRAWINGS

These and other features, aspects, and advantages of the present subject matter will become better understood when the following detailed description is read with reference to the accompanying drawings in which like characters represent like parts throughout the drawings, wherein:

FIG. 1 illustrates an embodiment of a magnetic resonance imaging (MRI) system suitable for use with the disclosed technique;

FIG. 2 illustrates a schematic diagram illustrating a deep learning-based multi-level denoising network configured to improve image quality of PROPELLER imaging, in accordance with aspects of the present disclosure;

FIG. 3 illustrates a flow chart of a method for improving image quality of periodically rotated overlapping parallel lines with enhanced reconstruction (PROPELLER) imaging (e.g., utilizing data from a single channel), in accordance with aspects of the present disclosure;

FIG. 4 illustrates a flow chart of a method for improving image quality of periodically rotated overlapping parallel lines with enhanced reconstruction (PROPELLER) imaging (e.g., utilizing data from multiple channels), in accordance with aspects of the present disclosure;

FIG. 5 illustrates a flow chart of a method for improving image quality of periodically rotated overlapping parallel lines with enhanced reconstruction (PROPELLER) imaging (e.g., with details of PROPELLER reconstruction), in accordance with aspects of the present disclosure;

FIG. 6 illustrates a flow chart of a method for training a deep learning-based denoising network, in accordance with aspects of the present disclosure;

FIG. 7 depicts periodically rotated overlapping parallel lines with enhanced reconstruction (PROPELLER) images of a spine comparing multi-level denoising and grid level denoising, in accordance with aspects of the present disclosure;

FIG. 8 depicts PROPELLER images of a knee comparing multi-level denoising and grid level denoising, in accordance with aspects of the present disclosure;

FIG. 9 depicts additional PROPELLER images of a knee comparing multi-level denoising and grid level denoising, in accordance with aspects of the present disclosure;

FIG. 10 depicts PROPELLER images of a spine comparing multi-level denoising and grid level denoising with super-resolution applied, in accordance with aspects of the present disclosure;

FIG. 11 depicts PROPELLER images of a pelvis comparing blade level and multi-level denoising, in accordance with aspects of the present disclosure;

FIG. 12 depicts an example of a PROPELLER ground truth image of a natural image, in accordance with aspects of the present disclosure;

FIG. 13 depicts a graph analyzing performance of grid level denoising relative to multi-level denoising on a natural image, in accordance with aspects of the present disclosure; and

FIG. 14 depicts examples of images from the analysis in FIG. 13, in accordance with aspects of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present subject matter, the articles “a,” “an,” “the,” and “said” are intended to mean that there are one or more of the elements. The terms “comprising,” “including,” and “having” are intended to be inclusive and mean that there may be additional elements other than the listed elements. Furthermore, any numerical examples in the following discussion are intended to be non-limiting, and thus additional numerical values, ranges, and percentages are within the scope of the disclosed embodiments.

While aspects of the following discussion are provided in the context of medical imaging, it should be appreciated that the disclosed techniques are not limited to such medical contexts. Indeed, the provision of examples and explanations in such a medical context is only to facilitate explanation by providing instances of real-world implementations and applications. However, the disclosed techniques may also be utilized in other contexts, such as image reconstruction for non-destructive inspection of manufactured parts or goods (i.e., quality control or quality review applications), and/or the non-invasive inspection of packages, boxes, luggage, and so forth (i.e., security or screening applications). In general, the disclosed techniques may be useful in any imaging or screening context or image processing or photography field where a set or type of acquired data undergoes a reconstruction process to generate an image or volume.

Deep learning (DL) approaches discussed herein may be based on artificial neural networks, and may therefore encompass one or more of deep neural networks, fully connected networks, convolutional neural networks (CNNs), unrolled neural networks, perceptrons, encoders-decoders, recurrent networks, transformer networks, wavelet filter banks, u-nets, general adversarial networks (GANs), dense neural networks (e.g., residual dense networks (RDNs), or other neural network architectures. The neural networks may include shortcuts, activations, batch-normalization layers, and/or other features. These techniques are referred to herein as DL techniques, though this terminology may also be used specifically in reference to the use of deep neural networks, which is a neural network having a plurality of layers.

As discussed herein, DL techniques (which may also be known as deep machine learning, hierarchical learning, or deep structured learning) are a branch of machine learning techniques that employ mathematical representations of data and artificial neural networks for learning and processing such representations. By way of example, DL approaches may be characterized by their use of one or more algorithms to extract or model high level abstractions of a type of data-of-interest. This may be accomplished using one or more processing layers, with each layer typically corresponding to a different level of abstraction and, therefore potentially employing or utilizing different aspects of the initial data or outputs of a preceding layer (i.e., a hierarchy or cascade of layers) as the target of the processes or algorithms of a given layer. In an image processing or reconstruction context, this may be characterized as different layers corresponding to the different feature levels or resolution in the data. In general, the processing from one representation space to the next-level representation space can be considered as one ‘stage’ of the process. Each stage of the process can be performed by separate neural networks or by different parts of one larger neural network.

In magnetic resonance imaging, noise is Gaussian in the acquired complex k-space as well as in the complex image. Periodically rotated overlapping parallel lines with enhanced reconstruction (PROPELLER) is an MR technique which provides high resolution magnetic resonance imaging with reduced motion artifacts by providing the capability to remove motion affected blades and by oversampling the low spatial frequencies. In PROPELLER, overlapping blades are acquired rotated around the k-space. Thus, the noise remains Gaussian in the blades. However, to obtain the end image, the blades need to be phase corrected and then gridded into uniform k-space coordinates (i.e., a Cartesian matrix), which causes the noise to become colored. Typically, denoising is performed after generating the complex image (when the noise is colored). But denoising models have been observed to perform better with Gaussian noise than colored noise. Attempts at denoising colored noise are reported to produce blurriness and degraded image quality. The denoising performance becomes drastically worse in the case of low signal-to-noise ratio data.

The present disclosure provides systems and methods for improving image quality of periodically rotated overlapping parallel lines with enhanced reconstruction (PROPELLER) imaging. In particular, the present disclosure provides for denoising individual blades in an image domain prior to phase correcting and gridding the blades (where the noise is still Gaussian). In very low signal-to-noise ratio cases, a deep learning-based model utilized to individually denoise the individual blades tends to act aggressively to remove noise, thereby, introducing blur. But, in each blade, the image is rotated differently and the deep learning-based model filters act along rows and columns only. This implies that the blur introduced by the deep learning-based model on each blade is along a relatively different angle. This blur when gridded manifests as streaks and small structures are prone to completely dissipate. This effect becomes more pronounced as the blade width becomes narrower. Thus, denoising individual blades may introduce artifacts that may arise after gridding together of independent deep learning artifacts such as blurring and half pixel shifts introduced in each blade. These artifacts may end up in structures streaking over after gridding.

In order to take advantage of the benefits of blade level denoising while also avoiding the downside, the disclosed embodiments provide systems and methods for multi-level denoising. In multi-level denoising, a deep learning-based denoising model (e.g., residual dense network model of 5 blocks) pretrained to remove Gaussian noise is first utilized. This is followed with parameter-less phase correction and adjoint non-uniform fast Fourier transform blocks to correct for different phase in each of the blades and to grid the blades into a Cartesian grid, respectively. A deep learning-based artifact removing model (e.g., light or lightweight residual dense network model having only 2 blocks) is then utilized. The entire set-up (i.e., deep learning-based multi-level denoising network) is then trained end to end to perform better denoising with less artifacts. In particular, both the deep learning-based denoising model and the deep learning-based artifact removing model are trained with backpropagated blade level loss and loss obtained after gridding of blades (i.e., grid level loss). The deep learning-based artifact removing model handles the blade level denoising artifacts that remain and smaller structures that are dissipated. A gridded image (obtained by gridding denoised blades) and a noisy gridded image (obtained after gridding the acquired noisy blades without denoising) are inputted into the deep learning-based artifact removing model to generate a denoised gridded image that is free of the blade level denoising model introduced artifacts. The deep learning-based artifact removing model is trained against a ground truth noise-free gridded image. The deep learning-based multi-level denoising network is configured to perform very clean denoising with high fidelity. By virtue of the training process, streaks are also removed. The training simulation can be extended to include motion robust gridding, where different blades are weighed differently before gridding and some blades may even be dropped. This causes non-uniform k-space which gives rise to streaks and the deep learning-based artifact removing model would become equipped to handles these streaks as well. The deep learning-based multi-level denoising network provides an end to end trainable deep learning framework completely immersive into PROPELLER reconstruction that is configured to achieve denoising with high fidelity and minimal artifacts.

The disclosed systems and methods include acquiring a plurality of blades of k-space data of a region of interest in a rotational manner around a center of k-space via a magnetic resonance imaging (MRI) scanner from a coil during a PROPELLER sequence, wherein each blade of the plurality of blades of k-space data includes a plurality of parallel phase encoding lines sampled in a phase encoding order. The disclosed systems and methods also include utilizing a deep learning-based multi-level denoising network to denoise each blade of the plurality of blades in an image domain to generate a plurality of denoised blades, to utilize a PROPELLER reconstruction algorithm to generate a denoised-gridded image from the plurality of denoised blades, and to remove individual-based denoising-induced artifacts from the denoised-gridded image to generate a denoised, artifact-free gridded image.

In certain embodiments, the deep learning-based multi-level denoising network includes a deep learning-based denoising model to denoise each blade of the plurality of blades in the image domain to generate the plurality of denoised blades and a deep learning-based artifact removing model to remove the individual-based denoising-induced artifacts from the denoised-gridded image to generate the denoised, artifact-free gridded image, and wherein the PROPELLER reconstruction algorithm includes adjoint non-uniform fast Fourier transform blocks configured to grid the plurality of denoised blades into a Cartesian grid. In certain embodiments, the deep learning-based multi-level denoising network includes a phase filter disposed between the deep learning-based denoising model and the adjoint non-uniform fast Fourier transform blocks that is configured to perform parameter-less phase correction to correct for different phase in each of the blades. In certain embodiments, the deep learning-based artifact removing model has fewer parameters than the deep learning-based denoising model.

In certain embodiments, the disclosed systems and methods include backpropagating a combination of both blade level loss and grid level loss to train the deep learning-based multi-level denoising network from end to end. In certain embodiments, the combination of both the blade level loss and the grid level loss are backpropagated to train both the deep learning-based denoising model and the deep learning-based artifact removing model.

In certain embodiments, the disclosed systems and methods include utilizing the PROPELLER reconstruction algorithm to generate a noisy gridded image from the plurality of blades that have not been denoised. In certain embodiments, the disclosed systems and methods include inputting both the denoised-gridded image and the noisy gridded image into the deep learning-based artifact removing model, wherein the deep learning-based artifact removing model utilizes both the denoised-gridded image and the noisy gridded image to generate the denoised, artifact-free gridded image. In certain embodiments, the disclosed systems and methods include applying super-resolution to the denoised, artifact-free gridded image to generate a higher resolution denoised, artifact-free gridded image that is further denoised. In certain embodiments, the denoised, artifact-free gridded image may be subject to other post-processing. In certain embodiments, the disclosed systems and methods further include writing the denoised, artifact-free gridded image to a DICOM file (e.g., for viewing or storage).

In certain embodiments, the plurality of blades of k-space data is acquired from a single channel of the coil. In certain embodiments, the plurality of blades of k-space data is acquired from a plurality of channels of the coil. In these embodiments, the disclosed systems and methods include combining the plurality of blades of k-space data acquired from the plurality of channels prior to utilizing the deep learning-based denoising network to denoise each blade of the plurality of blades in the image domain.

PROPELLER is generally used to suppress motion. Also, to suppress motion PROPELLER might be accelerated but this decreases the signal-to-noise ratio. Further, if the imaging system is further de-rated (with regard to number of coils and field-strength utilized), the signal-to-noise ratio falls below diagnosable quality. The disclosed systems and methods improve image quality in with regard to both signal-to-noise ratio and sharpness.

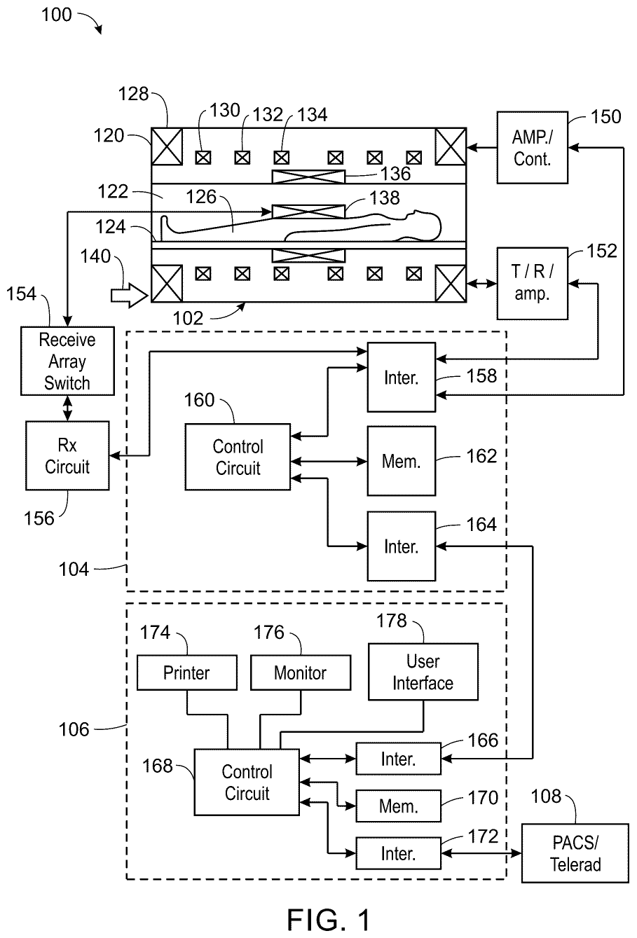

With the preceding in mind, FIG. 1 a magnetic resonance imaging (MRI) system 100 is illustrated schematically as including a scanner 102, scanner control circuitry 104, and system control circuitry 106. According to the embodiments described herein, the magnetic resonance imaging system 100 is generally configured to perform magnetic resonance imaging.

System 100 additionally includes remote access and storage systems or devices such as picture archiving and communication systems (PACS) 108, or other devices such as teleradiology equipment so that data acquired by the system 100 may be accessed on- or off-site. In this way, MR data may be acquired, followed by on- or off-site processing and evaluation. While the magnetic resonance imaging system 100 may include any suitable scanner or detector, in the illustrated embodiment, the system 100 includes a full body scanner 102 having a housing 120 through which a bore 122 is formed. A table 124 is moveable into the bore 122 to permit a patient 126 (e.g., subject) to be positioned therein for imaging selected anatomy within the patient.

Scanner 102 includes a series of associated coils for producing controlled magnetic fields for exciting the gyromagnetic material within the anatomy of the patient being imaged. Specifically, a primary magnet coil 128 is provided for generating a primary magnetic field, B₀, which is generally aligned with the bore 122. A series of gradient coils 130, 132, and 134 permit controlled magnetic gradient fields to be generated for positional encoding of certain gyromagnetic nuclei within the patient 126 during examination sequences. A radio frequency (RF) coil 136 (e.g., RF transmit coil) is configured to generate radio frequency pulses for exciting the certain gyromagnetic nuclei within the patient. In addition to the coils that may be local to the scanner 102, the system 100 also includes a set of receiving coils or RF receiving coils 138 (e.g., an array of coils) configured for placement proximal (e.g., against) to the patient 126. As an example, the receiving coils 138 can include cervical/thoracic/lumbar (CTL) coils, head coils, single-sided spine coils, and so forth. Generally, the receiving coils 138 are placed close to or on top of the patient 126 so as to receive the weak RF signals (weak relative to the transmitted pulses generated by the scanner coils) that are generated by certain gyromagnetic nuclei within the patient 126 as they return to their relaxed state.

The various coils of system 100 are controlled by external circuitry to generate the desired field and pulses, and to read emissions from the gyromagnetic material in a controlled manner. In the illustrated embodiment, a main power supply 140 provides power to the primary field coil 128 to generate the primary magnetic field, B₀. A power input (e.g., power from a utility or grid), a power distribution unit (PDU), a power supply (PS), and a driver circuit 150 may together provide power to pulse the gradient field coils 130, 132, and 134. The driver circuit 150 may include amplification and control circuitry for supplying current to the coils as defined by digitized pulse sequences output by the scanner control circuitry 104.

Another control circuit 152 is provided for regulating operation of the RF coil 136. Circuit 152 includes a switching device for alternating between the active and inactive modes of operation, wherein the RF coil 136 transmits and does not transmit signals, respectively. Circuit 152 also includes amplification circuitry configured to generate the RF pulses. Similarly, the receiving coils 138 are connected to switch 154, which is capable of switching the receiving coils 138 between receiving and non-receiving modes. Thus, the receiving coils 138 resonate with the RF signals produced by relaxing gyromagnetic nuclei from within the patient 126 while in the receiving mode, and they do not resonate with RF energy from the transmitting coils (i.e., coil 136) so as to prevent undesirable operation while in the non-receiving mode. Additionally, a receiving circuit 156 is configured to receive the data detected by the receiving coils 138 and may include one or more multiplexing and/or amplification circuits.

It should be noted that while the scanner 102 and the control/amplification circuitry described above are illustrated as being coupled by a single line, many such lines may be present in an actual instantiation. For example, separate lines may be used for control, data communication, power transmission, and so on. Further, suitable hardware may be disposed along each type of line for the proper handling of the data and current/voltage. Indeed, various filters, digitizers, and processors may be disposed between the scanner and either or both of the scanner and system control circuitry 104, 106.

As illustrated, scanner control circuitry 104 includes an interface circuit 158, which outputs signals for driving the gradient field coils and the RF coil and for receiving the data representative of the magnetic resonance signals produced in examination sequences. The interface circuit 158 is coupled to a control and analysis circuit 160. The control and analysis circuit 160 executes the commands for driving the circuit 150 and circuit 152 based on defined protocols selected via system control circuit 106.

Control and analysis circuit 160 also serves to receive the magnetic resonance signals and performs subsequent processing before transmitting the data to system control circuit 106. Scanner control circuit 104 also includes one or more memory circuits 162, which store configuration parameters, pulse sequence descriptions, examination results, and so forth, during operation.

Interface circuit 164 is coupled to the control and analysis circuit 160 for exchanging data between scanner control circuitry 104 and system control circuitry 106. In certain embodiments, the control and analysis circuit 160, while illustrated as a single unit, may include one or more hardware devices. The system control circuit 106 includes an interface circuit 166, which receives data from the scanner control circuitry 104 and transmits data and commands back to the scanner control circuitry 104. The control and analysis circuit 168 may include a CPU in a multi-purpose or application specific computer or workstation. Control and analysis circuit 168 is coupled to a memory circuit 170 to store programming code for operation of the magnetic resonance imaging system 100 and to store the processed image data for later reconstruction, display and transmission. The programming code may execute one or more algorithms that, when executed by a processor, are configured to perform reconstruction of acquired data as described below. In certain embodiments, the memory circuit 170 may store one or more neural networks for processing and/or reconstruction of acquired data (e.g., deep learning-based multi-level denoising network) as described below. In certain embodiments, image reconstruction may occur on a separate computing device having processing circuitry and memory circuitry.

A processing component (e.g., a microprocessor or processing circuitry) and a memory of the magnetic resonance imaging system 100, such as may be present in scanner control circuitry 104 and/or system control circuitry 106, may be used to execute stored software code, instructions, or routines for acquiring and processing the MR data. The term “code” or “software code” used herein refers to any instructions or set of instructions that control the magnetic resonance imaging system 100. The code or software code may exist in a computer-executable form, such as machine code, which is the set of instructions and data directly executed by the processing component of the scanner control circuitry 104 and/or system control circuitry 106, human-understandable form, such as source code, which may be compiled in order to be executed by the processing component of the scanner control circuitry 104 and/or system control circuitry 106, or an intermediate form, such as object code, which is produced by a compiler. In some embodiments, the magnetic resonance imaging system 100 may include a plurality of controllers.

As an example, the memory may store processor-executable software code or instructions (e.g., firmware or software), which are tangibly stored on a non-transitory computer readable medium. Additionally or alternatively, the memory 46 may store data. As an example, the memory may include a volatile memory, such as random access memory (RAM), and/or a nonvolatile memory, such as read-only memory (ROM), flash memory, a hard drive, or any other suitable optical, magnetic, or solid-state storage medium, or a combination thereof. Furthermore, processing component may include multiple microprocessors, one or more “general-purpose” microprocessors, one or more special-purpose microprocessors, and/or one or more application specific integrated circuits (ASICS), or some combination thereof. For example, the processing component may include one or more reduced instruction set (RISC) or complex instruction set (CISC) processors. The processing component may include multiple processors, and/or the memory may include multiple memory devices.

In certain embodiments, the processing component may be configured to acquire a plurality of blades of k-space data of a region of interest in a rotational manner around a center of k-space via a magnetic resonance imaging (MRI) scanner from a coil during a PROPELLER sequence, wherein each blade of the plurality of blades of k-space data includes a plurality of parallel phase encoding lines sampled in a phase encoding order. The processing component may also be configured to utilizing a deep learning-based multi-level denoising network to denoise each blade of the plurality of blades in an image domain to generate a plurality of denoised blades, to utilize a PROPELLER reconstruction algorithm to generate a denoised-gridded image from the plurality of denoised blades, and to remove individual-based denoising-induced artifacts from the denoised-gridded image to generate a denoised, artifact-free gridded image.

The deep learning-based multi-level denoising network includes a deep learning-based denoising model to denoise each blade of the plurality of blades in an image domain to generate the plurality of denoised blades and a deep learning-based artifact removing model to remove the individual-based denoising-induced artifacts from the denoised-gridded image to generate the denoised, artifact-free gridded image, and wherein the PROPELLER reconstruction algorithm includes adjoint non-uniform fast Fourier transform blocks configured to grid the plurality of denoised blades into a Cartesian grid. In certain embodiments, the deep learning-based multi-level denoising network includes a phase filter disposed between the deep learning-based denoising model and the adjoint non-uniform fast Fourier transform blocks that is configured to perform parameter-less phase correction to correct for different phase in each of the blades. In certain embodiments, the deep learning-based artifact removing model has fewer parameters than the deep learning-based denoising model.

In certain embodiments, the processing component is configured to backpropagate a combination of both blade level loss and grid level loss to train the deep learning-based multi-level denoising network from end to end. In certain embodiments, the combination of both the blade level loss and the grid level loss are backpropagated to train both the deep learning-based denoising model and the deep learning-based artifact removing model.

In certain embodiments, the processing component is configured to utilize the PROPELLER reconstruction algorithm to generate a noisy gridded image (e.g., via inverse two-dimensional (2D) fast Fourier transformation (FFT)) from the plurality of blades that have not been denoised. In certain embodiments, the processing component is configured to input both the denoised-gridded image and the noisy gridded image into the deep learning-based artifact removing model, wherein the deep learning-based artifact removing model utilizes both the denoised-gridded image and the noisy gridded image to generate the denoised, artifact-free gridded image. In certain embodiments, the processing component is configured to apply super-resolution to the denoised, artifact-free gridded image to generate a higher resolution denoised, artifact-free gridded image that is further denoised. In certain embodiments, the denoised, artifact-free gridded image may be subject to other post-processing. In certain embodiments, the processing component is configured to write the denoised, artifact-free gridded image to a DICOM file (e.g., for viewing or storage).

An additional interface circuit 172 may be provided for exchanging image data, configuration parameters, and so forth with external system components such as remote access and storage devices 108. Finally, the system control and analysis circuit 168 may be communicatively coupled to various peripheral devices for facilitating operator interface and for producing hard copies of the reconstructed images. In the illustrated embodiment, these peripherals include a printer 174, a monitor 176, and user interface 178 including devices such as a keyboard, a mouse, a touchscreen (e.g., integrated with the monitor 176), and so forth.

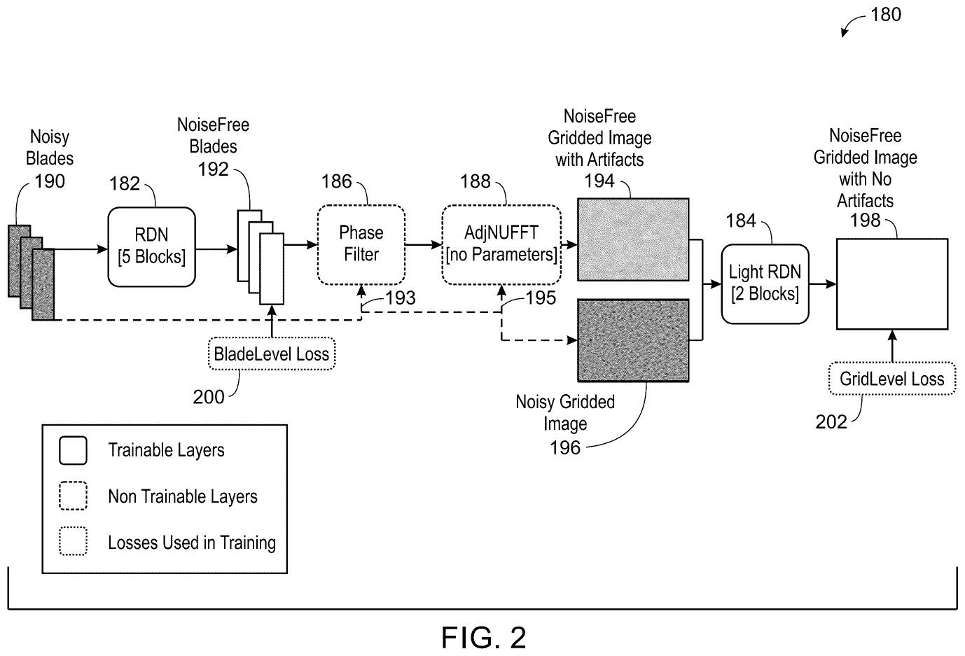

FIG. 2 is a schematic diagram illustrating a deep learning-based multi-level denoising network 180 configured to improve image quality of PROPELLER imaging. The deep learning-based multi-level denoising network 180 includes a deep learning-based denoising model 182 and a deep learning-based artifact removing model 184. The deep learning-based multi-level denoising network 180 also includes a phase filter 186 and adjoint non-uniform fast Fourier transform (NUFFT) layers or blocks 188 disposed between the deep learning-based denoising model 182 and the deep learning-based artifact removing model 184. The phase filter 186 is disposed between the deep learning-based denoising model 182 and the adjoint NUFFT layers or blocks 188. Both the deep learning-based denoising model 182 and the deep learning-based artifact removing model 184 are trainable layers. Both the phase filter 186 and the adjoint NUFFT layers 188 are not trainable layers. The adjoint NUFFT layers 188 have no parameters.

As depicted, the deep learning-based denoising model 182 is a residual dense network model having 5 blocks. In certain embodiments, both the type of learning model and/or the number of blocks/layer/parameters may vary. The deep learning-based artifact removing model 184 is a residual dense network model having 2 blocks. As depicted, the deep learning-based artifact removing model 184 is light or lightweight deep learning-based model. The deep learning-based artifact removing model 184 has fewer parameters than the deep learning-based denoising model 182 as it does not take as many parameters to remove artifacts. In certain embodiments, the deep learning-based artifact removing model 184 may be of the same size or larger than the deep learning-based denoising model 182.

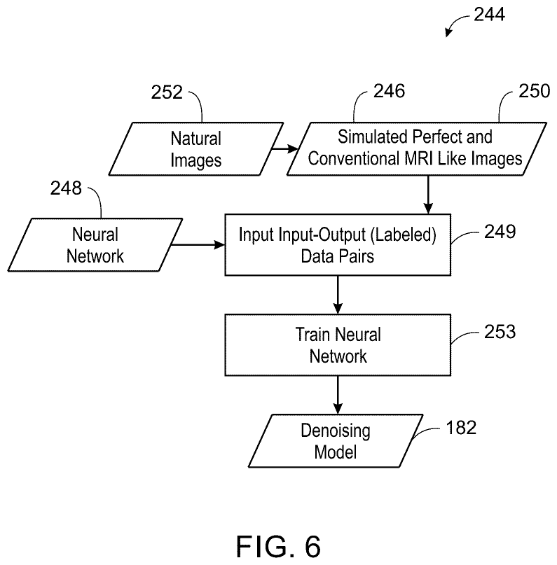

A plurality of blades 190 (e.g., noisy blades) in an image domain (e.g., derived from blades of k-space data via inverse 2D FFT) of a region of interest are input into the deep learning-based denoising model 182. The plurality of blades of k-space data are acquired (e.g., from a single channel or multiple channels) in a rotational manner (e.g., rotated approximately 10 to 20 degrees between blade acquisitions) around a center of k-space via a magnetic resonance imaging (MRI) scanner (e.g., magnetic resonance imaging scanner 102 in FIG. 1) from a coil (e.g., RF receiving coil such as a body coil or surface coil) during a PROPELLER sequence. Each blade of the plurality of blades of k-space data includes a plurality of parallel phase encoding lines sampled in a phase encoding order (e.g., having a rectilinear shape) using fast spin echo or gradient echo methods (i.e., each blade 190 is filled by an echo train of a respective MR pulse sequence). The deep learning-based denoising model 182 is configured to denoise each blade 190 (e.g., individually) of the plurality of blades 190 in the image domain to generate a plurality of denoised blades 192 (e.g., noise free blades). The deep learning-based denoising model 182 is pre-trained or primed to predict noise present in a Cartesian acquisition image (e.g., MR image). The deep learning-based denoising model 182 is built to be size invariant. The training of the deep learning-based denoising model 182 is as described below in FIG. 6.

The denoised blades 192 are then inputted into the phase filter 186. The phase filter 186 is configured to perform parameter-less phase correction to correct for different phase in each of the blades 192. Performing phase correction for each denoised blade 192 assures its point of rotation is exactly at the center of k-space. After phase correction, the phase-corrected, denoised blades 192 are inputted into the adjoint NUFFT layers 188. The adjoint NUFFT layers 188 are configured to grid the plurality of denoised blades 192 into a Cartesian grid to generate a denoised (noise free)-gridded image 194 (e.g., a first complex image). The adjoint NUFFT layers 188 are is configured to perform corrections for bulk in-plane rotation and in-plane translation of the object and to perform correlation-weighting to minimize the data from blades containing motion or displacement errors.

In addition, the noisy blades 190 are inputted into the phase filter 186 as indicated by arrow 193. The phase filter 186 is configured to perform parameter-less phase correction to correct for different phase in each of the blades 190. After phase correction, the phase-corrected, noisy blades 190 are inputted into the adjoint NUFFT layers 188 as indicated by arrow 195. The adjoint NUFFT layers 188 are configured to grid the plurality of noisy blades 190 into a Cartesian grid to generate a noisy gridded image 196 (e.g., a second complex image).

Both the denoised (noise free)-gridded image 194 and the noisy gridded image 196 are inputted into the deep learning-based artifact removing model 184. The deep learning-based artifact removing model 184 is configured to remove individual-based denoising-induced artifacts from the denoised-gridded image 194 to generate a denoised, artifact-free gridded image 198 utilizing both the denoised (noise free)-gridded image 194 and the noisy gridded image 196.

Both blade level loss 200 (loss obtained after individual denoising of blades) and grid level loss 202 (loss obtained after gridding of blades) are combined with different respective weights given to the blade level loss 200 and the grid level loss 202. The combined blade level loss 200 and the grid level loss 202 are backpropagated to train the deep learning-based multi-level denoising network 180 from end to end. In particular, the combination of both the blade level loss 200 and the grid level loss 202 are backpropagated to train both the deep learning-based denoising model 182 and the deep learning-based artifact removing model 184.

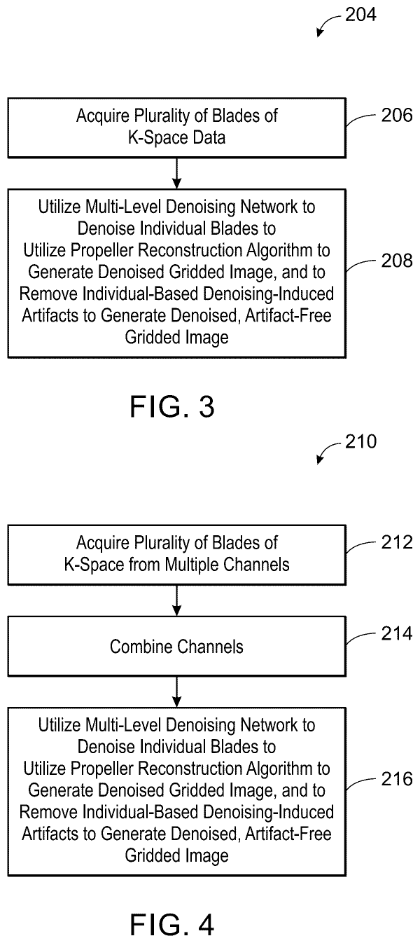

FIG. 3 is a flow chart of a method 204 for improving image quality of PROPELLER imaging. One or more steps of the method 204 may be performed by processing circuitry of the magnetic resonance imaging system 100 in FIG. 1 or a remote computing system. For example, the processing circuitry may part of the scanner control circuitry 104 and/or system control circuitry 106 of the magnetic resonance imaging system 100. One or more steps of the method 204 may be performed simultaneously and/or in a different order shown in FIG. 3. The method 204 is performed on data acquired from a single channel of a coil (e.g., RF reeving coil such as a body coil or surface coil).

The method 204 includes acquiring a plurality of blades of k-space data of a region of interest in a rotational manner (e.g., rotated approximately 10 to 20 degrees between blade acquisitions) around a center of k-space via a magnetic resonance imaging scanner (e.g., magnetic resonance imaging scanner 102 in FIG. 1) from a coil (e.g., RF receiving coil such as a body coil or surface coil) during a PROPELLER sequence (block 206). Each blade of the plurality of blades of k-space data includes a plurality of parallel phase encoding lines sampled in a phase encoding order (e.g., having a rectilinear shape) using fast spin echo or gradient echo methods (i.e., each blade is filled by an echo train of a respective MR pulse sequence). The plurality of blades are converted to the image domain via inverse 2D FFT.

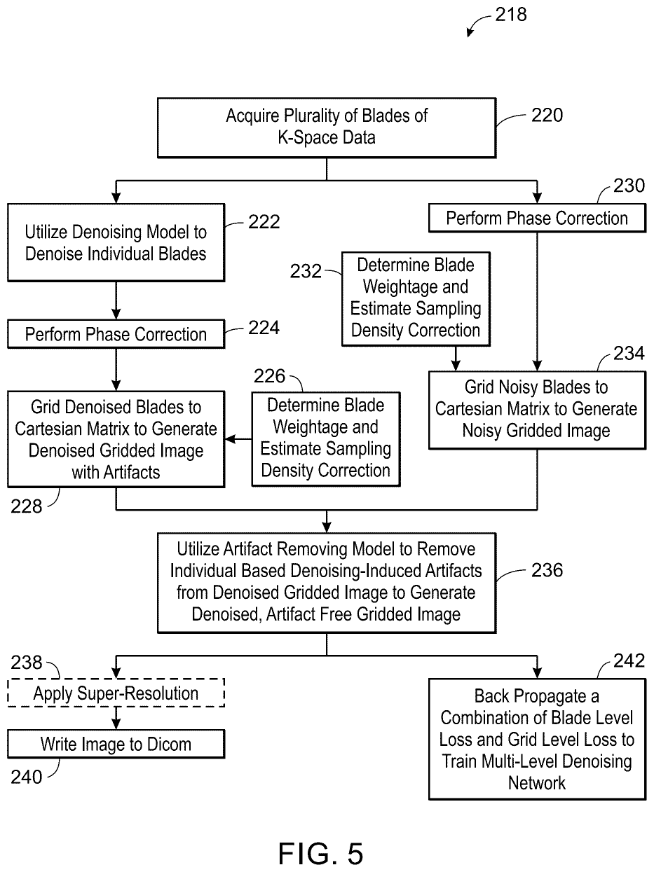

The method 204 also includes utilizing a deep learning-based multi-level denoising network to denoise each blade (e.g., individually) of the plurality of blades in an image domain to generate a plurality of denoised blades, to utilize a PROPELLER reconstruction algorithm to generate a denoised-gridded image from the plurality of denoised blades, and to remove individual-based denoising-induced artifacts from the denoised-gridded image to generate a denoised, artifact-free gridded image (block 208). In particular, a deep learning-based denoising model to denoise each blade of the plurality of blades in the image domain to generate the plurality of denoised blades and a deep learning-based artifact removing model to remove the individual-based denoising-induced artifacts from the denoised-gridded image to generate the denoised, artifact-free gridded image. The deep learning-based denoising model is trained to predict noise present in a Cartesian acquisition image (e.g., MR image). In addition, the PROPELLER reconstruction algorithm includes adjoint non-uniform fast Fourier transform blocks configured to grid the plurality of denoised blades into a Cartesian grid. The PROPELLER reconstruction algorithm includes parameter-less phase correction for each blade to assure its point of rotation is exactly at the center of k-space, corrections for bulk in-plane rotation and in-plane translation of the object, and correlation-weighting to minimize the data from blades containing motion or displacement errors. In certain embodiments, the denoised, artifact-free gridded image may be further processed (as described below in FIG. 5) prior to writing the image into a Digital Imaging and Communications in Medicine (DICOM) file.

FIG. 4 is a flow chart of a method 210 for improving image quality of PROPELLER imaging (e.g., utilizing data from multiple channels). One or more steps of the method 210 may be performed by processing circuitry of the magnetic resonance imaging system 100 in FIG. 1 or a remote computing system. For example, the processing circuitry may part of the scanner control circuitry 104 and/or system control circuitry 106 of the magnetic resonance imaging system 100. One or more steps of the method 210 may be performed simultaneously and/or in a different order shown in FIG. 4. The method 210 is performed on data acquired from a plurality of channels of a coil (e.g., RF reeving coil such as a body coil).

The method 210 includes acquiring a plurality of blades of k-space data (e.g., from multiple channels) of a region of interest in a rotational manner (e.g., rotated approximately 10 to 20 degrees between blade acquisitions) around a center of k-space via a magnetic resonance imaging scanner (e.g., magnetic resonance imaging scanner 102 in FIG. 1) from a coil (e.g., RF receiving coil such as a body coil or surface coil) during a PROPELLER sequence (block 212). Each blade of the plurality of blades of k-space data includes a plurality of parallel phase encoding lines sampled in a phase encoding order (e.g., having a rectilinear shape) using fast spin echo or gradient echo methods i.e., each blade is filled by an echo train of a respective MR pulse sequence). The method 210 also includes combining the plurality of blades of k-space data acquired from the plurality of channels prior to utilizing a deep learning-based multi-level denoising network to denoise each blade of the plurality of blades of k-space data (i.e., corresponding blades of k-space data from the channels are combined) (block 214). The plurality of blades are converted to the image domain via inverse 2D FFT.

The method 210 also includes utilizing a deep learning-based multi-level denoising network to denoise (e.g., individually) each blade (e.g., combined blade) of the plurality of blades in the image domain to generate a plurality of denoised blades, to utilize a PROPELLER reconstruction algorithm to generate a denoised-gridded image from the plurality of denoised blades, and to remove individual-based denoising-induced artifacts from the denoised-gridded image to generate a denoised, artifact-free gridded image (block 216). In particular, a deep learning-based denoising model to denoise each blade of the plurality of blades in the image domain to generate the plurality of denoised blades and a deep learning-based artifact removing model to remove the individual-based denoising-induced artifacts from the denoised-gridded image to generate the denoised, artifact-free gridded image. The deep learning-based denoising model is trained to predict noise present in a Cartesian acquisition image (e.g., MR image). In addition, the PROPELLER reconstruction algorithm includes adjoint non-uniform fast Fourier transform blocks configured to grid the plurality of denoised blades into a Cartesian grid. The PROPELLER reconstruction algorithm includes parameter-less phase correction for each blade to assure its point of rotation is exactly at the center of k-space, corrections for bulk in-plane rotation and in-plane translation of the object, and correlation-weighting to minimize the data from blades containing motion or displacement errors. In certain embodiments, the denoised, artifact-free gridded image may be further processed (as described below in FIG. 5) prior to writing the image into a Digital Imaging and Communications in Medicine (DICOM) file.

FIG. 5 is a flow chart of a method 218 for improving image quality of PROPELLER imaging (e.g., with details of PROPELLER reconstruction). One or more steps of the method 218 may be performed by processing circuitry of the magnetic resonance imaging system 100 in FIG. 1 or a remote computing system. For example, the processing circuitry may part of the scanner control circuitry 104 and/or system control circuitry 106 of the magnetic resonance imaging system 100. One or more steps of the method 218 may be performed simultaneously and/or in a different order shown in FIG. 5. The method 218 is performed on data acquired from either a single channel (e.g., as described in the method 204 in FIG. 3) or a plurality of channels (e.g., as described in the method 210 in FIG. 4) of a coil (e.g., RF reeving coil such as a body coil or surface coil).

The method 218 includes acquiring a plurality of blades (e.g., noisy blades) of k-space data (e.g., from a single channel or multiple channels) of a region of interest in a rotational manner (e.g., rotated approximately 10 to 20 degrees between blade acquisitions) around a center of k-space via a magnetic resonance imaging scanner (e.g., magnetic resonance imaging scanner 102 in FIG. 1) from a coil (e.g., RF receiving coil such as a body coil or surface coil) during a PROPELLER sequence (block 220). Each blade of the plurality of blades of k-space data includes a plurality of parallel phase encoding lines sampled in a phase encoding order (e.g., having a rectilinear shape) using fast spin echo or gradient echo methods (i.e., each blade is filled by an echo train of a respective MR pulse sequence). The plurality of blades are converted to the image domain via inverse 2D FFT

The method 218 also includes utilizing a deep learning-based denoising model of a deep learning-based multi-level denoising network to denoise each blade (or each combined blade) of the plurality of blades in the image domain to generate a plurality of denoised blades (block 222). The deep learning-based denoising network is trained to predict noise present in a Cartesian acquisition image (e.g., MR image). The deep learning-based denoising network is built to be size invariant. The training of the deep learning-based denoising network is described below in FIG. 6.

As noted above, the PROPELLER reconstruction algorithm includes parameter-less phase correction for each blade to assure its point of rotation is exactly at the center of k-space, corrections for bulk in-plane rotation and in-plane translation of the object, and correlation-weighting to minimize the data from blades containing motion or displacement errors. The method 218 further includes performing parameter-less phase correction, via a phase filter, on the plurality of denoised blades (block 224). Performing phase correction for each blade assures its point of rotation is exactly at the center of k-space. The method 218 still further includes determining the weightage for each blade and estimating sampling density correction for each blade (block 226). Based on the weights and the estimated sampling density corrections to be applied to the denoised blades, the method 218 includes gridding, via an adjoint NUFFT, all of the denoised blades of k-space into a Cartesian matrix (e.g., uniform k-space co-ordinates) to generate a denoised, gridded image with artifacts (block 228). The blocks 224 and 226 of the method 218 ensure corrections for bulk in-plane rotation and in-plane translation of the object, while the correlation-weighting minimizes the data from the blades containing motion or displacement errors.

The method 218 further includes performing parameter-less phase correction, via a phase filter, on plurality of blades (noisy blades) (block 230). The method 218 still further includes determining the weightage for each noisy blade and estimating sampling density correction for each noisy blade (block 232). Based on the weights and the estimated sampling density corrections to be applied to the noisy blades, the method 218 includes gridding, via an adjoint NUFFT, all of the noisy blades of k-space into a Cartesian matrix (e.g., uniform k-space co-ordinates) to generate a noisy gridded image (block 234).

The method 218 includes utilizing a deep learning-based artifact removing model to remove the individual-based denoising-induced artifacts from the denoised-gridded image to generate a denoised, artifact-free gridded image (block 236). Both the denoised (noise free)-gridded image and the noisy gridded image are inputted into the deep learning-based artifact removing model. The deep learning-based artifact removing model is configured to remove individual-based denoising-induced artifacts from the denoised-gridded image to generate a denoised, artifact-free gridded image utilizing both the denoised (noise free)-gridded image and the noisy gridded image.

In certain embodiments, the method 218 also includes applying super-resolution to the denoised, artifact-free gridded image to generate a higher resolution denoised, artifact-free gridded image that is further denoised (e.g., free of blur) (block 238). In certain embodiments, the denoised, artifact-free gridded image may be subject to other post-processing. The method 218 further includes writing the image (e.g., denoised, artifact-free gridded image or higher resolution denoised, artifact-free gridded image) to a DICOM file (e.g., for viewing or storage) (block 240).

The method 218 even further includes backpropagating a combination of both blade level loss and grid level loss to train the deep learning-based multi-level denoising network from end to end (block 242). The combination of both the blade level loss and the grid level loss are backpropagated to train both the deep learning-based denoising model and the deep learning-based artifact removing model.

FIG. 6 illustrates a flow chart of a method 244 for training (e.g., initial training) a deep learning-based denoising model 182. As noted above, the deep learning-based denoising model is primed or trained prior to be utilized with the deep learning-based multi-level denoising network. One or more steps of the method 244 may be performed by processing circuitry of the magnetic resonance imaging system 100 in FIG. 1 or a remote computing system. For example, the processing circuitry may part of the scanner control circuitry 104 and/or system control circuitry 106 of the magnetic resonance imaging system 100.

The method 244 includes inputting input-output (e.g., labeled) data pairs 246 into a neural network 248 (block 249). In certain embodiments, the neural network 248 is a residual dense network. In certain embodiments, input-output data pairs 246 include near perfect (i.e., sharp, lacking artifacts, and high signal-to-noise ratio) and conventional MRI like images 250 simulated from natural images 252. The method 244 also includes training the neural network 248 on the input-output data pairs 246 utilizing supervised learning to generate the deep learning-based denoising model 182 (block 253). In certain embodiments, at least some pairs of the input-output data pairs 246 include skewed aspect ratios to augment training to improve the performance of the deep learning-based denoising model 182. The deep learning-based denoising model 182 is trained to predict noise in Cartesian acquired images (e.g., MR images). Due to the training on natural images with sufficient variability and the residue to be predicted remains in the same Gaussian distribution, the deep learning-based can be utilized on blade level images. In certain embodiments, the images of the input-output data pairs 246 may be 256×256. However, the deep learning-based denoising model 182 is built to be size invariant.

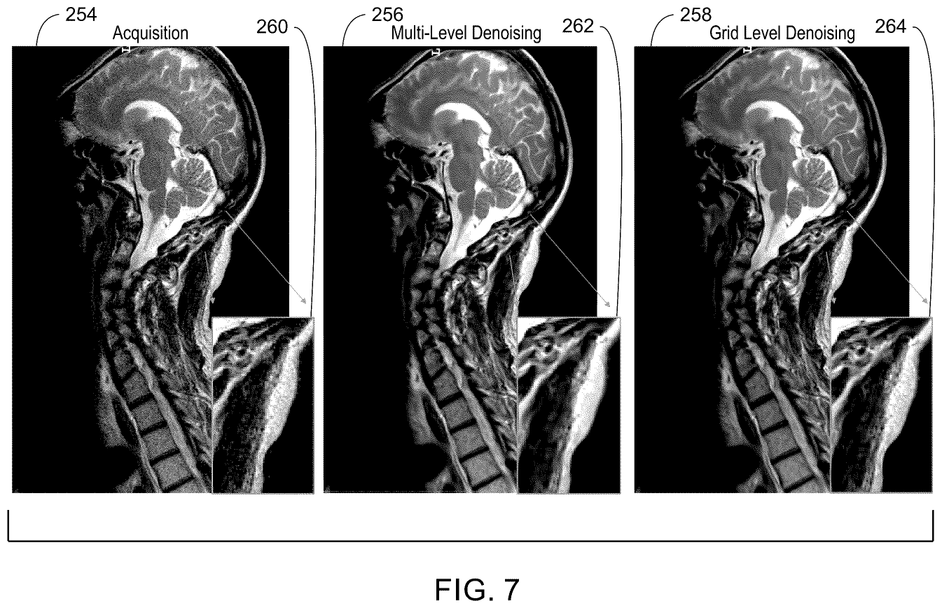

FIGS. 7-11 illustrate the effectiveness of performing multi-level denoising. FIG. 7 depicts PROPELLER images of a spine comparing multi-level denoising and grid level denoising. Images 254, 256, and 258 were acquired of a spine (with a sagittal T2 scan) utilizing PROPELLER with a 1.5 Tesla (T) magnetic resonance imaging scanner using a body coil. Image 254 is a PROPELLER image without denoising. Image 256 is the corresponding PROPELLER image with multi-level denoising performed utilizing the deep learning-based multi-level denoising network described above. Image 258 is the corresponding PROPELLER image with grid level denoising performed (i.e., denoising performed after the gridding of the blades). Both images 256 and 258 are 100 percent denoised. The quality (e.g., signal-to-noise ratio and sharpness) is improved in images 256 and 258 compared to the image 254. However, image 258 has patchy denoising in some regions, for example, when looking at respective zoomed regions 260, 262, and 264 of the images 254, 256, and 258 as seen in the zoomed region 264.

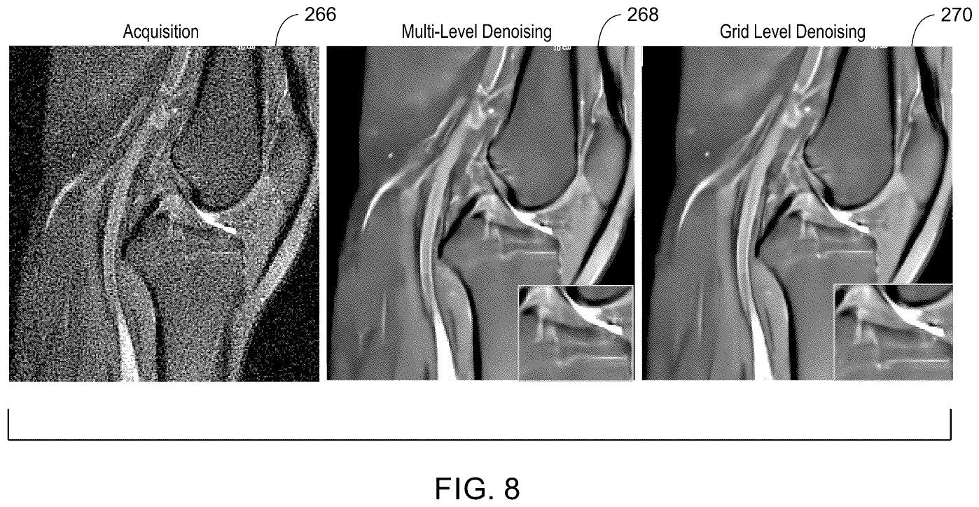

FIG. 8 depicts PROPELLER images of a knee comparing multi-level denoising and grid level denoising. Images 266, 268, and 270 were acquired of a knee (with a sagittal proton density-weighted fat-suppressed scan) utilizing PROPELLER with a 1.5 Tesla (T) magnetic resonance imaging scanner using a body coil. Image 266 is a PROPELLER image without denoising. Image 268 is the corresponding PROPELLER image with multi-level denoising performed utilizing the deep learning-based multi-level denoising network described above. Image 270 is the corresponding PROPELLER image with grid level denoising performed (i.e., denoising performed after the gridding of the blades). Both images 268 and 270 are 100 percent denoised. The quality (e.g., signal-to-noise ratio and sharpness) is improved in images 268 and 270 compared to the image 266. However, the model utilized for grid level denoising has exaggerated certain structures as seen in the image 270.

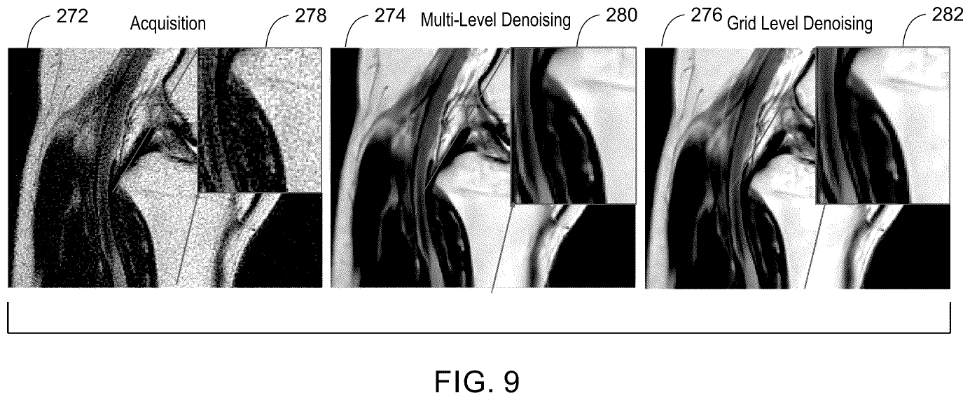

FIG. 9 depicts additional PROPELLER images of a knee comparing multi-level denoising and grid level denoising. Images 272, 274, and 276 were acquired of a knee (with a sagittal T2 scan) utilizing PROPELLER with a 1.5 Tesla (T) magnetic resonance imaging scanner using a body coil. Image 272 is a PROPELLER image without denoising. Image 274 is the corresponding PROPELLER image with multi-level denoising performed utilizing the deep learning-based multi-level denoising network described above. Image 276 is the corresponding PROPELLER image with grid level denoising performed (i.e., denoising performed after the gridding of the blades). Both images 274 and 276 are 100 percent denoised. The quality (e.g., signal-to-noise ratio and sharpness) is improved in images 274 and 276 compared to the image 272. However, the model utilized for grid level denoising has wiped/blurred out some structures when looking at respective zoomed regions 278, 280, and 282 of the images 272, 274, and 276 as seen in the zoomed region 282.

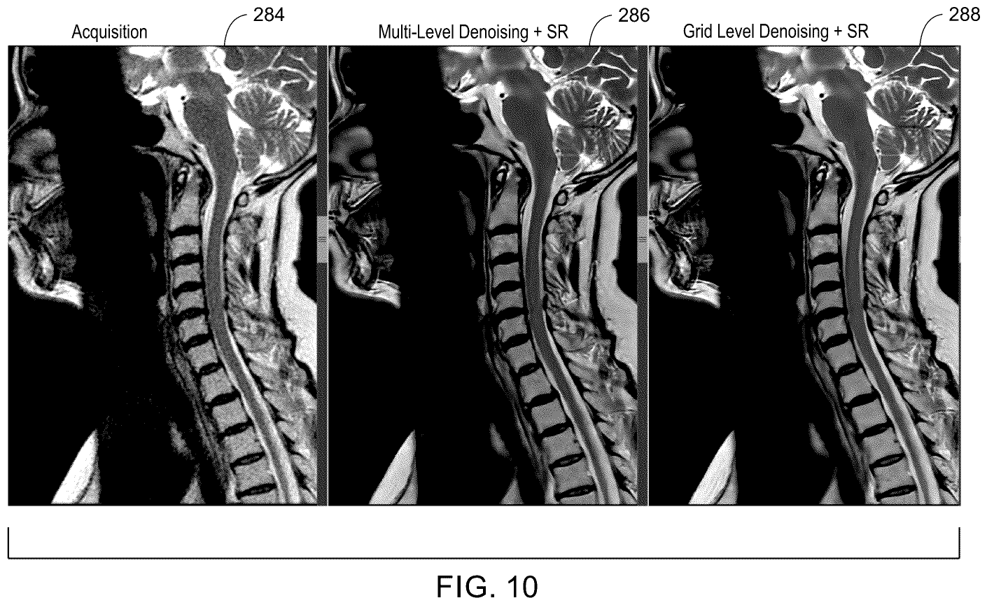

FIG. 10 depicts PROPELLER images of a spine comparing multi-level denoising and grid level denoising with super-resolution applied. Images 284, 286, and 288 were acquired of a spine (with a T2 scan) utilizing PROPELLER with a 0.5 Tesla (T) magnetic resonance imaging scanner (which generates low signal-to-noise ratio data) using a heck neck array coil. Image 284 is a PROPELLER image without denoising. Super-resolution was applied to generate the images 286 and 288. Image 286 is the corresponding PROPELLER image with multi-level denoising performed utilizing the deep learning-based multi-level denoising network described above. Image 288 is the corresponding PROPELLER image with grid level denoising performed (i.e., denoising performed after the gridding of the blades). Both images 286 and 288 are 100 percent denoised. The quality (e.g., signal-to-noise ratio and sharpness) is improved in images 286 and 288 compared to the image 284. In addition, the signal-to-noise ratio is decent in both images 286 and 288.

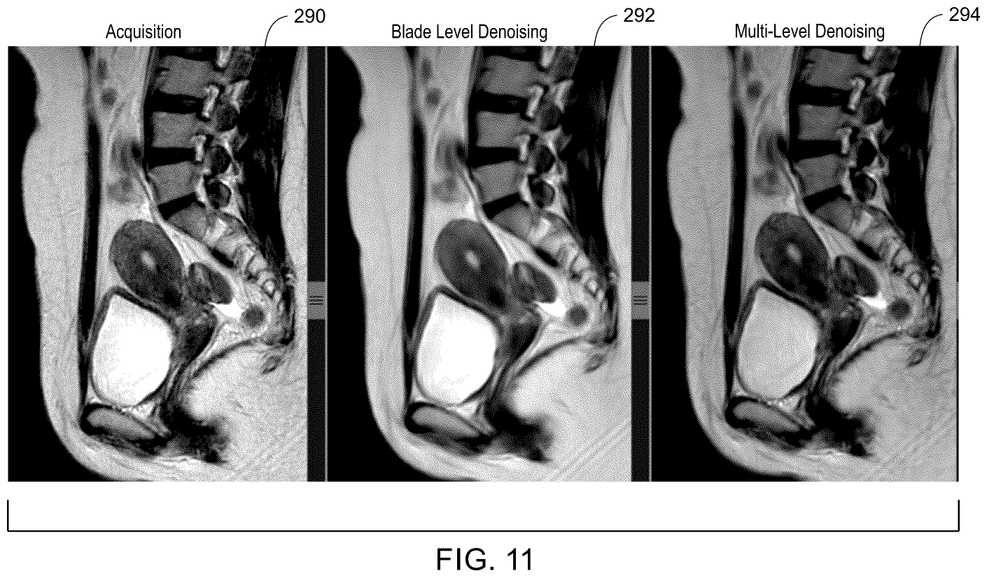

FIG. 11 depicts PROPELLER images of a pelvis comparing blade level denoising and multi-level denoising. Images 290, 292, and 294 were acquired of a pelvis (with a sagittal T2 scan) utilizing PROPELLER with a 1.5 Tesla (T) magnetic resonance imaging scanner using a body coil. Image 290 is a PROPELLER image without denoising. Image 292 is the corresponding PROPELLER image with blade level denoising performed utilizing the deep learning-based blade level denoising model (i.e., but not utilizing a deep learning-based artifact removing model to remove the individual-based denoising-induced artifacts). Image 294 is the corresponding PROPELLER image with multi-level denoising performed utilizing the deep learning-based multi-level denoising network described above. Both images 292 and 294 are 100 percent denoised. The quality (e.g., signal-to-noise ratio and sharpness) is improved in images 292 and 294 compared to the image 290. Comparing image 294 to image 292, it can be observed that the multi-level noising network resolves structures much sharper than the blade level denoising model.

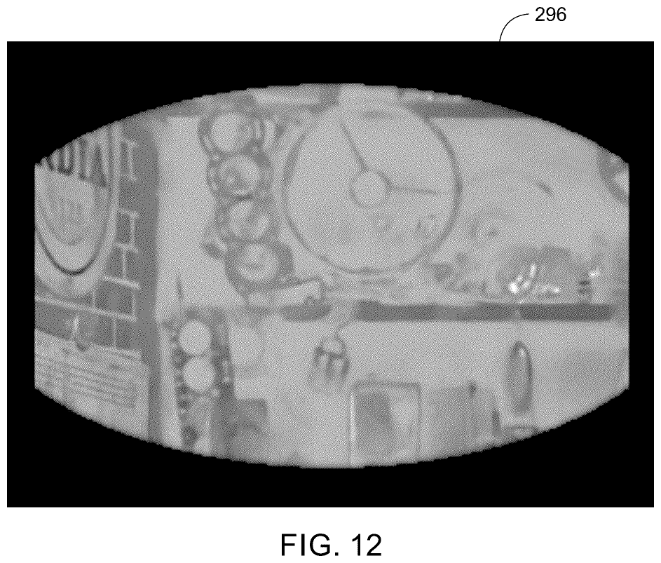

To evaluate the performance of multi-level denoising relative to grid level denoising single channel PROPELLER images were simulated from natural images. FIG. 12 depicts an example of a PROPELLER ground truth image 296 of a natural image. From the natural image, 19 blades were simulated of dimension 322×32 and gridded together to form the PROPELLER ground truth image 296. Different levels of random Gaussian were added to the blades and gridded to obtain a noisy PROPELLER image. Denoising was performed using grid level denoising and multi-level denoising techniques.

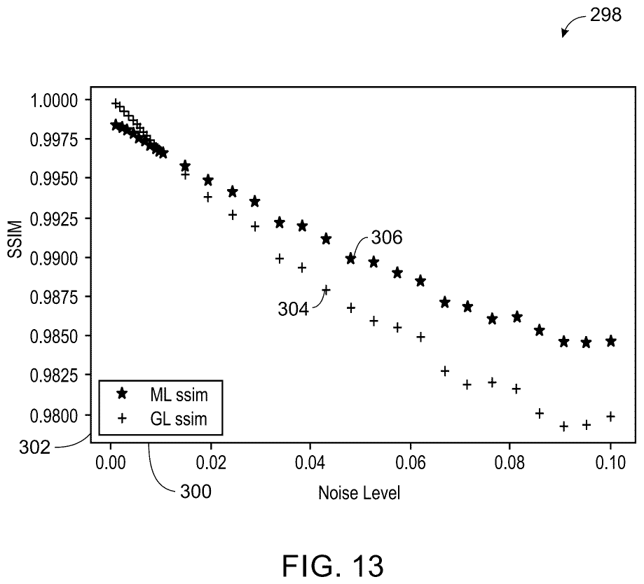

The results are depicted in FIG. 13. FIG. 13 depicts a graph 298 analyzing performance of grid level denoising relative to multi-level denoising on a natural image. The graph 298 includes an x-axis 300 representing noise level and a y-axis 302 representing structural similarity index (SSIM). Plot 304 represents the SSIM between a ground truth PROPELLER image and PROPELLER images derived utilizing the grid level denoising technique on noisy PROPELLER images. Plot 306 represents the SSIM between a ground truth PROPELLER image and PROPELLER images derived utilizing the multi-level denoising technique on noisy PROPELLER images. It is observed, as depicted in the graph 298, that as the noise added increases, the ability of the noise to completely morph or bury the structures after gridding increases and hence, it becomes impossible for grid level denoising to recover those structures. On the other hand, as the multi-level denoising model attempts to remove noise at blade level, where noise remains pixelwise statistically independent Gaussian noise, the possibility of recovering those structures is high.

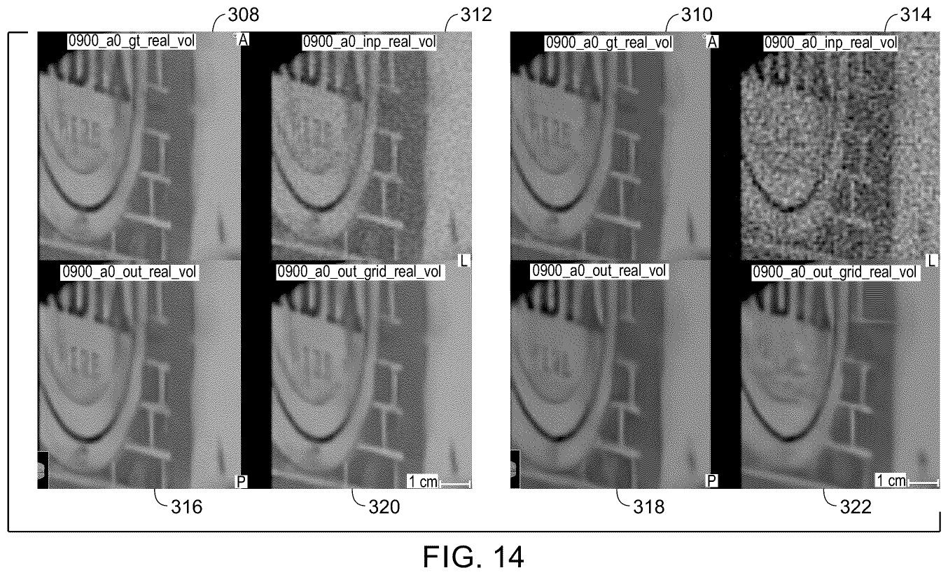

FIG. 14 depicts examples of images from the analysis of simulated PROPELLER images of a natural image in FIG. 13. Images 308 and 310 are the same ground truth PROPELLER image. Images 312 and 314 are noisy PROPELLER images simulated with different noise levels, respectively. Images 316 and 318 are the corresponding PROPELLER images to the images 312 and 314, respectively, obtained by multi-level denoising. Images 320 and 322 are the corresponding PROPELLER images to the images 312 and 314, respectively, obtained by grid level denoising. As noted above, the multi-level denoising is better at recovering the structures.

Technical effects of the disclosed subject matter include providing system and methods for improving image quality of periodically rotated overlapping parallel lines with enhanced reconstruction (PROPELLER) imaging. In particular, the present disclosure provides for denoising individual blades in image domain prior to phase correcting and gridding the blades (where the noise is still Gaussian). Technical effects o of the disclosed subject matter includes providing a deep learning-based multi-level denoising network that provides an end to end trainable deep learning framework completely immersive into PROPELLER reconstruction that is configured to achieve denoising with high fidelity and minimal artifacts. Technical effects of the disclosed subject matter include improve image quality in with regard to both signal-to-noise ratio and sharpness.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

This written description uses examples to disclose the present subject matter, including the best mode, and also to enable any person skilled in the art to practice the subject matter, including making and using any devices or systems and performing any incorporated methods. The patentable scope of the subject matter is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A computer-implemented method for improving image quality of periodically rotated overlapping parallel lines with enhanced reconstruction (PROPELLER) imaging, comprising:
acquiring, via a processor, a plurality of blades of k-space data of a region of interest in a rotational manner around a center of k-space via a magnetic resonance imaging (MRI) scanner from a coil during a PROPELLER sequence, wherein each blade of the plurality of blades of k-space data comprises a plurality of parallel phase encoding lines sampled in a phase encoding order; and
utilizing, via the processor, a deep learning-based multi-level denoising network to denoise each blade of the plurality of blades in an image domain to generate a plurality of denoised blades, to utilize a PROPELLER reconstruction algorithm to generate a denoised-gridded image from the plurality of denoised blades, and to remove individual-based denoising-induced artifacts from the denoised-gridded image to generate a denoised, artifact-free gridded image.

2. The computer-implemented method of claim 1, wherein the deep learning-based multi-level denoising network comprises a deep learning-based denoising model to denoise each blade of the plurality of blades in the image domain to generate the plurality of denoised blades and a deep learning-based artifact removing model to remove the individual-based denoising-induced artifacts from the denoised-gridded image to generate the denoised, artifact-free gridded image, and wherein the PROPELLER reconstruction algorithm comprises adjoint non-uniform fast Fourier transform blocks configured to grid the plurality of denoised blades into a Cartesian grid.

3. The computer-implemented method of claim 2, wherein the deep learning-based artifact removing model has fewer parameters than the deep learning-based denoising model.

4. The computer-implemented method of claim 2, further comprising backpropagating, via the processor, a combination of both blade level loss and grid level loss to train the deep learning-based multi-level denoising network from end to end.

5. The computer-implemented method of claim 4, wherein the combination of both the blade level loss and the grid level loss are backpropagated to train both the deep learning-based denoising model and the deep learning-based artifact removing model.

6. The computer-implemented method of claim 2, further comprising utilizing, via the processor, the PROPELLER reconstruction algorithm to generate a noisy gridded image from the plurality of blades that have not been denoised.

7. The computer-implemented method of claim 6, further comprising inputting, via the processor, both the denoised-gridded image and the noisy gridded image into the deep learning-based artifact removing model, wherein the deep learning-based artifact removing model utilizes both the denoised-gridded image and the noisy gridded image to generate the denoised, artifact-free gridded image.

8. The computer-implemented method of claim 1, further comprising applying, via the processor, super-resolution to the denoised, artifact-free gridded image to generate a higher resolution denoised, artifact-free gridded image that is further denoised.

9. A system for improving image quality of periodically rotated overlapping parallel lines with enhanced reconstruction (PROPELLER) imaging, comprising:
a memory encoding processor-executable routines; and
a processor configured to access the memory and to execute the processor-executable routines, wherein the processor-executable routines, when executed by the processor, cause the processor to:
acquire a plurality of blades of k-space data of a region of interest in a rotational manner around a center of k-space via a magnetic resonance imaging (MRI) scanner from a coil during a PROPELLER sequence, wherein each blade of the plurality of blades of k-space data comprises a plurality of parallel phase encoding lines sampled in a phase encoding order; and
utilize a deep learning-based multi-level denoising network to denoise each blade of the plurality of blades in an image domain to generate a plurality of denoised blades, to utilize a PROPELLER reconstruction algorithm to generate a denoised-gridded image from the plurality of denoised blades, and to remove individual-based denoising-induced artifacts from the denoised-gridded image to generate a denoised, artifact-free gridded image.

10. The system of claim 9, wherein the deep learning-based multi-level denoising network comprises a deep learning-based denoising model to denoise each blade of the plurality of blades in the image domain to generate the plurality of denoised blades and a deep learning-based artifact removing model to remove the individual-based denoising-induced artifacts from the denoised-gridded image to generate the denoised, artifact-free gridded image, and wherein the PROPELLER reconstruction algorithm comprises an adjoint non-uniform fast Fourier transform blocks configured to grid the plurality of denoised blades into a Cartesian grid.

11. The system of claim 10, wherein the deep learning-based artifact removing model has fewer parameters than the deep learning-based denoising model.

12. The system of claim 10, wherein the processor-executable routines, when executed by the processor, further cause the processor to backpropagate a combination of both blade level loss and grid level loss to train the deep learning-based multi-level denoising network from end to end.

13. The system of claim 12, wherein the combination of both the blade level loss and the grid level loss are backpropagated to train both the deep learning-based denoising model and the deep learning-based artifact removing model.

14. The system of claim 10, wherein the processor-executable routines, when executed by the processor, further cause the processor to utilize the PROPELLER reconstruction algorithm to generate a noisy gridded image from the plurality of blades that have not been denoised.

15. The system of claim 14, wherein the processor-executable routines, when executed by the processor, further cause the processor to input both the denoised-gridded image and the noisy gridded image into the deep learning-based artifact removing model, wherein the deep learning-based artifact removing model utilizes both the denoised-gridded image and the noisy gridded image to generate the denoised, artifact-free gridded image.

16. The system of claim 9, wherein the processor-executable routines, when executed by the processor, further cause the processor to apply super-resolution to the denoised, artifact-free gridded image to generate a higher resolution denoised, artifact-free gridded image that is further denoised.

17. A non-transitory computer-readable medium, the computer-readable medium comprising processor-executable code that when executed by a processor, causes the processor to:
acquire a plurality of blades of k-space data of a region of interest in a rotational manner around a center of k-space via a magnetic resonance imaging (MRI) scanner from a coil during a periodically rotated overlapping parallel lines with enhanced reconstruction (PROPELLER) sequence, wherein each blade of the plurality of blades of k-space data comprises a plurality of parallel phase encoding lines sampled in a phase encoding order; and
utilize a deep learning-based multi-level denoising network to denoise each blade of the plurality of blades in an image domain to generate a plurality of denoised blades, to utilize a PROPELLER reconstruction algorithm to generate a denoised-gridded image from the plurality of denoised blades, and to remove individual-based denoising-induced artifacts from the denoised-gridded image to generate a denoised, artifact-free gridded image.

18. The computer-readable medium of claim 17, wherein the deep learning-based multi-level denoising network comprises a deep learning-based denoising model to denoise each blade of the plurality of blades in the image domain to generate the plurality of denoised blades and a deep learning-based artifact removing model to remove the individual-based denoising-induced artifacts from the denoised-gridded image to generate the denoised, artifact-free gridded image, and wherein the PROPELLER reconstruction algorithm comprises an adjoint non-uniform fast Fourier transform blocks configured to grid the plurality of denoised blades into a Cartesian grid.

19. The computer-readable medium of claim 18, wherein the processor-executable code, when executed by the processor, further causes the processor to further backpropagate a combination of both blade level loss and grid level loss to train the deep learning-based multi-level denoising network from end to end.

20. The computer-readable medium of claim 19, wherein the combination of both the blade level loss and the grid level loss are backpropagated to train both the deep learning-based denoising model and the deep learning-based artifact removing model.
